(19) United States
(12) Patent Application Publication
(10) Pub. No.: US 2025/0280550 A1
(43) Pub. Date: Sep. 4, 2025

(54) CAPACITOR AND METHOD FOR MANUFACTURING THE SAME

(71) Applicant: KOREA INSTITUTE OF SCIENCE AND TECHNOLOGY, Seoul (KR)

(72) Inventors: Hong Keun CHUNG, Seoul (KR); Ji-Soo JANG, Seoul (KR); Sunghoon HUR, Seoul (KR); Hyun-Cheol SONG, Seoul (KR); Seung Hyub BAEK, Seoul (KR); Ji-Won CHOI, Seoul (KR); Jin Sang KIM, Wanju-gun (KR); Chong Yun KANG, Seoul (KR); Seong Keun KIM, Seoul (KR)

(73) Assignee: KOREA INSTITUTE OF SCIENCE AND TECHNOLOGY, Seoul (KR)

(21) Appl. No.: 18/824,167

(22) Filed: Sep. 4, 2024

(30) Foreign Application Priority Data
Mar. 4, 2024 (KR) 10-2024-0030526

(51) Int. Cl. H01L 21/02

(52) U.S. Cl. CPC H10D 1/694; H01L 21/0228; H10D 1/682

(57) ABSTRACT

The present invention relates to a capacitor and a method for manufacturing the same that can improve a dielectric property and a leakage current property of the capacitor by enabling the deposition of a crystalline dielectric film under a low process temperature of 500° C. or lower simultaneously with fundamentally blocking the generation of interfacial oxides when depositing oxides having a perovskite crystal structure through atomic layer deposition (ALD). The capacitor according to the present invention is characterized by comprising a lower electrode having a structure in which a platinum ultra-thin film layer is laminated on a ruthenium thin film layer; a dielectric film laminated on the platinum ultra-thin film layer; and an upper electrode laminated on the dielectric film.

### CROSS REFERENCE TO RELATED APPLICATION

The present application claims the priority of Korean Patent Application No. 10-2024-0030526 filed on Mar. 4, 2024, in the Korean Intellectual Property Office, the entire contents of which are incorporated herein by reference for all purposes.

### BACKGROUND OF THE INVENTION

### 1. Field of the Invention

The present invention relates to a capacitor and a method for manufacturing the same, and more specifically, is directed to a capacitor and a method for manufacturing the same that can improve a dielectric property and a leakage current property of the capacitor by enabling the deposition of a crystalline dielectric film under a low process temperature of 500° C. or less simultaneously with fundamentally blocking the generation of interfacial oxides when depositing oxides having a perovskite crystal structure through atomic layer deposition (ALD).

[Description about National Research and Development Support]

This study was supported by the technology development program of Ministry of Trade, Industry and Energy, Republic of Korea (Project No. 1415187483) under the Korea Institute of Science and Technology.

Further, this study was supported by the technology development program of Ministry of Science and ICT, Republic of Korea (Project No. 1711201879) under the Korea Electronics and Telecommunications Research Institute

### 2. Description of the Related Art

As the miniaturization of a DRAM device accelerates, the effective surface area of a DRAM capacitor that stores charges has decreased and the required capacitance value per unit area has further increased. High-k materials are expected to replace the existing DRAM capacitor dielectric film because they can secure high capacitance per unit area. Among the various high-k materials, SrTiO₃, which has a perovskite crystal structure, has a high dielectric constant (k) of 200 or more in its bulk state, and therefore is attracting attention as a next-generation dielectric film material.

Further, research on ruthenium (Ru) as a lower electrode of the next-generation

DRAM capacitor is being actively conducted. Ruthenium has a low specific resistance and is effective in suppressing a leakage current when combined with the high-k material.

Accordingly, a lot of research are being conducted on a capacitor which applies ruthenium (Ru) as the lower electrode and SrTiO₃ as the dielectric film. In addition, in order to manufacture a capacitor that meets the miniaturization of DRAM, since thin films of nm thickness must be laminated with excellent step coverage, atomic layer deposition (ALD) is preferred as a method for depositing SrTiO₃ (See Non-Patent Documents 1 and 2).

However, in case SrTiO₃ is deposited on the ruthenium (Ru) lower electrode using the atomic layer deposition (ALD), there is a problem that performance of the capacitor is deteriorated due to oxidation and oxygen scavenging effect of ruthenium. In the process of depositing SrTiO₃ through the atomic layer deposition (ALD), ozone (O₃) is supplied to oxidize a titanium (Ti) precursor. In this case, a reaction of ruthenium (Ru) with ozone (O₃) causes production of ruthenium oxide (RuO₂) on a surface of ruthenium (Ru), whereby strontium oxide (SrOₓ), which is interfacial oxides, is formed at an interface between ruthenium (Ru) and SrTiO₃ due to oxygen scavenging effect of strontium (Sr). To be precise, due to a high reactivity of strontium (Sr), an oxygen component of ruthenium oxide (RuO₂) reacts with strontium (Sr) to form strontium oxide (SrOₓ).

Since strontium oxide (SrOₓ) formed at the interface between ruthenium (Ru) and SrTiO₃ forms a Sr-rich composition during the initial growth of the SrTiO₃ thin film, it deviates from the stoichiometric ratio and suppresses crystallization. This reduces a dielectric constant of the dielectric film and increases an equivalent oxide film thickness (EOT), which acts as a factor that deteriorates performance of the capacitor.

In order to suppress the generation of such interfacial oxides, Non-Patent Document 2 proposed a technology that minimizes the reaction between strontium (Sr) and ruthenium oxide (RuO₂) by laminating TiO₂ on the lower electrode of ruthenium (Ru) before depositing SrTiO₃, but there was a problem that a thickness of the capacitor was increased with TiO₂ lamination and the equivalent oxide film thickness (EOT) was deteriorated.

Patent Documents 1 to 3 discloses that various metals are applied as materials of the lower electrode and high-k materials such as (Ba,Sr)TiO₃ and SrTiO₃ are applied as the dielectric film so that they can be deposited through atomic layer deposition (ALD). However, the review of Experimental Examples (or Examples) of these Patents indicates that (Ba,Sr)TiO₃ or SrTiO₃ are laminated as the dielectric film on the lower electrode of ruthenium (Ru) through the atomic layer deposition (ALD). Accordingly, the inventions disclosed in Patent Documents 1 to 3 are also not free from the problems caused by the generation of strontium oxide (SrOₓ).

The formation of interfacial oxides such as strontium oxide (SrOₓ) is a common phenomenon indicating not only when applying SrTiO₃ but also when applying other oxides having the perovskite crystal structure.

Meanwhile, in addition to the problem caused by the generation of strontium oxide (SrOₓ), another difficulty in the technology of depositing SrTiO₃ on the lower electrode of ruthenium (Ru) through the atomic layer deposition (ALD) is a high crystallization temperature.

A process temperature of the atomic layer deposition (ALD) in the deposition of SrTiO₃ is 300-400° C., but since the deposited SrTiO₃ is in an amorphous state, a subsequent heat treatment process for crystallization is essential. Patent Document 3 discloses that SrTiO₃ is deposited at a process temperature of 300° C., and a heat treatment process is performed at 500° C. (First to Third Examples) or 650° C. (Fourth example) for crystallization of SrTiO₃.

Non-Patent Documents 1 and 2 describe that crystallization of SrTiO₃ is possible by applying 370° C. as a process temperature for the atomic layer deposition (ALD), which is limited to the case of depositing SrTiO₃ on a seed layer. In the case of the absence of the seed layer, it is stated that SrTiO₃ is in an amorphous state, and therefore it can be seen that a subsequent heat treatment process is required for the crystallization. For reference, Non-Patent Document 1 indicates that a heat treatment process of 650° C. is applied for the crystallization of amorphous SrTiO₃.

Since a process temperature of the DRAM device is limited to 500° C. or lower to prevent deterioration, high-temperature heat treatment to crystallize SrTiO₃ may cause deterioration of the DRAM device. In addition, in case the high-temperature heat treatment is applied to crystallize SrTiO₃, there is a problem in that crystal grains are formed to increase surface roughness, thereby deteriorating the leakage current property.

### DOCUMENTS OF RELATED ART

### Patent Documents

(Patent Document 1) Korea Patent Laid-open Publication No. 2010-0089522 (published on Aug. 12, 2010)
(Patent Document 2) Korean Patent Laid-open Publication No. 2009-0051634 (published on May 22, 2009)
(Patent Document 3) Japanese Patent Laid-open Publication No. 2010-192520 (published on Sep. 2, 2010)

### Non-Patent Documents

(Non-Patent Document 1) Enhanced electrical properties of SrTiO₃ thin films grown by atomic layer deposition at high temperature for dynamic random access memory applications, Lee et al., Appl. Phys. Lett. 92, 222903 (2008)
(Non-Patent Document 2) Atomic Layer Deposition of SrTiO₃ Thin Films with Highly Enhanced Growth Rate for Ultrahigh Density Capacitors, Lee et al., Chem. Mater. 2011, 23, 2227-2236

### SUMMARY OF THE INVENTION

The present invention is developed to solve the above problems, and a purpose of the present invention is to provide a capacitor and a method for manufacturing the same that can improve a dielectric property and a leakage current property of the capacitor by enabling the deposition of a crystalline dielectric film under a low process temperature of 500° C. or less simultaneously with fundamentally blocking the generation of interfacial oxides when depositing oxides having a perovskite crystal structure through atomic layer deposition (ALD).

A capacitor according to the present invention for achieving the above purpose is characterized by comprising a lower electrode having a structure in which a platinum ultra-thin film layer is laminated on a ruthenium thin film layer; a dielectric film laminated on the platinum ultra-thin film layer; and an upper electrode laminated on the dielectric film.

The platinum ultra-thin film layer has a thickness of 50 Å or less.

The platinum ultra-thin film layer has a thickness of 10 Å or less.

The platinum ultra-thin film layer has a thickness of 4 to 10 Å.

The dielectric film consists of oxides having a perovskite crystal structure, wherein the oxides having the perovskite crystal structure are any one of SrTiO₃, (Ba, Sr)TiO₃(BST), BaTiO₃, PZT, PLZT, (Ba,Sr)(Zr,Ti)O₃(BSZTO), Sr(Zr,Ti)O₃(SZTO), Ba(Zr,Ti)O₃(BZTO), (Ba, Sr)ZrO₃(BSZO), SrZrO₃ or BaZrO₃, or a combination thereof.

The capacitor has an equivalent oxide film thickness (EOT) of 4.0 Å or less and a leakage current value of 8.4×10⁻⁸ A/cm² at an operating voltage of 0.8 V.

A method for manufacturing a capacitor according to the present invention is characterized by comprising the steps of: preparing a substrate consisting of a non-metallic material; forming a ruthenium thin film layer on some areas of the substrate; forming a platinum ultra-thin film layer on the ruthenium thin film layer through area-selective atomic layer deposition; forming a dielectric film on the platinum ultra-thin film layer through the atomic layer deposition; and forming an upper electrode on the dielectric film.

In the step of forming the platinum ultra-thin film layer on the ruthenium thin film layer through the area-selective atomic layer deposition, the platinum ultra-thin film layer is formed only on the ruthenium thin film layer having relatively higher surface energy due to a difference in the surface energy between the non-metallic material and the ruthenium thin film layer.

In the step of forming the dielectric film on the platinum ultra-thin film layer through the atomic layer deposition, a process temperature of the atomic layer deposition is 400° C. or less.

The present method may further comprise the step of heat treating the dielectric film at a temperature of 500° C. or lower after the step of forming the dielectric film on the platinum ultra-thin film layer through the atomic layer deposition.

The capacitor and the method for manufacturing the same according to the present invention have the following effects.

The generation of interfacial oxides such as strontium oxide (SrOₓ) at an interface between the platinum ultra-thin film layer and the dielectric film can be fundamentally blocked by applying, as the lower electrode, a structure in which the platinum ultra-thin film layer is laminated on the ruthenium thin film layer and laminating, as the dielectric film, oxides with a perovskite crystal structure on the platinum ultra-thin film layer. A dielectric property and a leakage current property of the capacitor is improved by not generating the interfacial oxides.

### BRIEF DESCRIPTION OF THE DRAWINGS

FIG. 1 is a schematic diagram showing a capacitor according to an embodiment of the present invention.

FIG. 2 is a flowchart for indicating a method for manufacturing a capacitor according to an embodiment of the present invention.

FIG. 3A is a schematic diagram showing that a platinum ultra-thin film layer is formed only on a ruthenium thin film layer by area-selective atomic layer deposition.

FIGS. 3B and 3C show each of the AES analysis results and the line profile analysis results for a platinum ultra-thin film layer prepared according to Experimental Example 1.

FIGS. 4A and 4B show each of the results of measuring a Sr areal density and a Sr atomic ratio of a SrTiO₃ thin film according to a deposition thickness of a platinum ultra-thin film layer.

FIGS. 5A and 5B show each of the results of measuring a Sr areal density and a Sr atomic ratio in a thin film according to the number of repetitions of the SrTiO₃ thin film deposition cycle.

FIG. 6 shows the results of analyzing GIXRD of SrTiO₃ prepared according to Experimental Example 4.

FIGS. 7A and 7B show each property of a dielectric constant and an equivalent oxide film thickness (EOT) of a capacitor according to a deposition thickness of SrTiO₃.

FIGS. 8A and 8B show each property of a dielectric constant and an equivalent oxide film thickness (EOT) of a capacitor according to a deposition thickness of SrTiO₃ that was heat treated at 500° C.

FIG. 9 is the experimental results showing a leakage current property depending on an equivalent oxide film thickness (EOT) before and after applying the subsequent heat treatment process.

FIGS. 10A and 10B show the SEM images of a SrTiO₃ surface before and after applying the subsequent heat treatment process.

### DETAILED DESCRIPTION OF THE INVENTION

The present invention proposes a technology capable of manufacturing a capacitor with excellent dielectric property and leakage current property under a low process temperature of 500° C. or less in implementing the capacitor in which oxides having a perovskite crystal structure are applied as a dielectric film.

In the present invention, the oxides having the perovskite crystal structure refer to any one of SrTiO₃, (Ba,Sr)TiO₃(BST), BaTiO₃, PZT, PLZT, (Ba,Sr)(Zr,Ti)O₃(BSZTO), Sr(Zr,Ti)O₃(SZTO), Ba(Zr,Ti)O₃(BZTO), (Ba,Sr)ZrO₃(BSZO), SrZrO₃ or BaZrO₃, or a combination thereof. Hereinafter, for convenience of explanation, SrTiO₃ is described as an embodiment.

As previously described in the ‘Background of the Invention’, in case ruthenium (Ru) is applied as a lower electrode to form SrTiO₃ through atomic layer deposition (ALD), ozone (O₃) which is supplied for oxidation of a titanium (Ti) precursor reacts with ruthenium (Ru) to form ruthenium oxide (RuO₂), and highly reactive strontium (Sr) reacts with an oxygen component of ruthenium oxide (RuO₂) to form strontium oxide (SrOₓ) which is interfacial oxides. These interfacial oxides (SrOₓ) change a composition ratio of the SrTiO₃ thin film in a direction of the thin film thickness, thereby interfering with production of the crystalline SrTiO₃, which acts as factors that not only deteriorate the dielectric property and the leakage current property of the capacitor, but also increase an equivalent oxide film thickness (EOT) and raise a process temperature.

The present invention applies a structure in which platinum (Pt) of an ultra-thin film, i.e., a platinum ultra-thin film layer, is laminated on ruthenium (Ru), as a lower electrode of the capacitor, and SrTiO₃ is laminated on the platinum ultra-thin film layer, thereby fundamentally blocking generation of interfacial oxides such as SrOₓ. As the interfacial oxides are not generated, the dielectric property and the leakage current property of the capacitor are improved, thereby being capable of reducing the equivalent oxide film thickness (EOT) and lowering a crystallization temperature of SrTiO₃.

Meanwhile, since platinum (Pt) has low chemical reactivity and is not easily oxidized, it has been considered as the lower electrode of the capacitor. However, its application as the lower electrode of the capacitor has been limited because it is not easy to etch pattern. Patent Documents 1 to 3 also indicate platinum (Pt) as one of the materials applicable to the lower electrode of the capacitor, but most Examples or Experimental Examples thereof disclose that ruthenium (Ru) is applied as the lower electrode and fails to describe that SrTiO₃ is laminated as a dielectric film on the platinum (Pt) lower electrode. Likewise, although platinum (Pt) has excellent chemical stability, it has been difficult to apply platinum (Pt) to the lower electrode of the capacitor due to difficulty in etching.

The present invention solves this difficulty in platinum (Pt) etch through area-selective atomic layer deposition using nucleation delay characteristic. That is, the present invention can complete a structure in which a platinum ultra-thin film layer is laminated on ruthenium (Ru) without etch patterning of platinum (Pt) by depositing platinum (Pt) using the area selective atomic layer deposition.

A method for the area-selective atomic layer deposition is divided into a method using a deposition inhibitor and a method using nucleation delay. The former method is to grow a thin film only in growth area of a substrate by coating the deposition inhibitor on a non-growth area of the substrate, and the latter method is to grow the thin film only in the growth area through substrate selectivity. The present invention utilizes the latter method.

If platinum (Pt) is deposited through the atomic layer deposition with a metal layer being laminated on some areas of a substrate consisting of non-metallic material, platinum (Pt) tends to be deposited on the metal layer having higher surface energy without being deposited on the non-metallic material having relatively lower surface energy. In other words, platinum (Pt) is deposited only on specific areas of the substrate due to the nucleation delay characteristic. Of course, if the atomic layer deposition cycle is continuously repeated, platinum (Pt) is deposited on the non-metallic material as well.

Therefore, in case the number of repetitions of the atomic layer deposition cycle is within a certain level, since platinum (Pt) is deposited only on specific areas of the substrate due to nucleation delay characteristic, separate etch patterning for platinum (Pt) is not required. In other words, this means that when platinum (Pt) is deposited to a thickness of the ultra-thin film, platinum (Pt) can be deposited on specific areas of the substrate without separate etch patterning.

Based on this principle, the present invention can complete a structure in which the platinum ultra-thin film layer is laminated on ruthenium (Ru) without separate etch patterning for platinum (Pt), wherein the structure is adopted as the lower electrode of the capacitor.

As oxides having a perovskite crystal structure, for example, SrTiO₃, are deposited on the platinum ultra-thin film layer rather than ruthenium (Ru), the reaction between ozone (O₃) and ruthenium (Ru) is fundamentally blocked so that the interfacial oxides such as strontium oxide (SrOₓ) are not generated between the platinum ultra-thin film layer and SrTiO₃. As described previously, the interfacial oxides such as strontium oxide (SrOₓ) cause stoichiometric non-uniformity of SrTiO₃, and therefore the fact that no interfacial oxides are generated means that SrTiO₃ conforming to stoichiometry is formed from the beginning of the atomic layer deposition, and crystalline SrTiO₃ can be formed during the atomic layer deposition (ALD) process.

Referring to Experimental Examples of the present invention described later, it can be confirmed that the crystalline SrTiO₃ is formed on the platinum (Pt) lower electrode through the atomic layer deposition (ALD) performed at a process temperature of 380° C. In the case of Non-Patent Documents 1 and 2 using a ruthenium (Ru) lower electrode, it can be confirmed that amorphous SrTiO₃ is formed even though the atomic layer deposition (ALD) is performed at 370° C. that is similar to the process temperature of the present invention, which is caused by the generation of strontium oxide (SrOₓ) due to oxidation of the ruthenium (Ru) lower electrode and oxygen scavenging of strontium (Sr).

Through the method of the present invention wherein the interfacial oxides such as strontium oxide (SrOₓ) are not generated, various problems associated with application of the ruthenium (Ru) lower electrode are solved. First, since the interfacial oxides are not generated, crystallization of SrTiO₃ occurs during the atomic layer deposition (ALD) process so that the subsequent heat treatment process for crystallization of SrTiO₃ can be omitted. In other words, the crystalline SrTiO₃ can be formed at a process temperature of 400° C. or lower, and thus satisfy the limit temperature condition of 500° C. or lower for a DRAM process. In addition, as the dielectric film consists of only the crystalline SrTiO₃ without strontium oxide (SrOₓ), a thickness of the capacitor device can be miniaturized and the equivalent oxide film thickness (EOT) can be reduced to implement a capacitor having high capacitance. Herein, the equivalent oxide film thickness (EOT) is an indicator of a dielectric property of the dielectric film and means a thickness of the dielectric film having the same capacitance as that of SiO₂. The dielectric film of the next-generation DRAM capacitor is required to have an equivalent oxide film thickness (EOT) of 4 Å or less.

Hereinafter, a capacitor and a method for manufacturing the same according to an embodiment of the present invention will be described in detail with reference to the drawings.

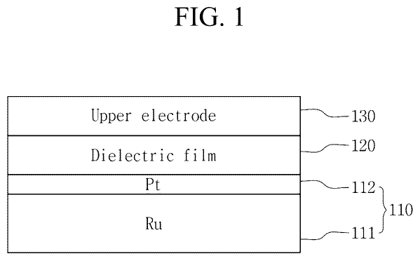

Referring to FIG. 1, a capacitor according to an embodiment of the present invention has a structure in which a dielectric film 120 and an upper electrode 130 are sequentially laminated on a lower electrode 110.

The lower electrode 110 is a combination of ruthenium (Ru) and platinum (Pt), and has a structure in which a platinum ultra-thin film layer 112 is laminated on a ruthenium thin film layer 111. A thickness of the ruthenium thin film layer 111 is not limited, but may have a thickness of 1 to 50 nm, and the platinum ultra-thin film layer 112 has a thickness of 5 nm or less, preferably a thickness of 4 to 50 Å. If the thickness of the platinum ultra-thin film layer 112 is less than 4 Å, interfacial oxides are generated between the platinum ultra-thin film layer 112 and the dielectric film 120 to cause a problem in that a dielectric property and a leakage current property of the capacitor are deteriorated. If the thickness of the platinum ultra-thin film layer 112 exceeds 5 nm, etch patterning of the platinum ultra-thin film layer 112 is required. A critical significance of the thickness of the platinum ultra-thin film layer 112 can be confirmed through the experimental results described later.

The dielectric film 120 consists of oxides having a perovskite crystal structure. The oxides with the perovskite crystal structure are any one of SrTiO₃, (Ba,Sr)TiO₃(BST), BaTiO₃, PZT, PLZT, (Ba,Sr)(Zr,Ti)O₃(BSZTO), Sr(Zr,Ti)O₃(SZTO), Ba(Zr,Ti)O₃(BZTO), (Ba,Sr)ZrO₃(BSZO), SrZrO₃ or BaZrO₃, or a combination thereof. The dielectric film 120 may have a thickness of 5 to 100 nm.

The upper electrode 130 may consist of platinum (Pt) or a known electrode material.

As described above, the capacitor according to an embodiment of the present invention has been described. Next, a method for manufacturing the capacitor according to an embodiment of the present invention will be described.

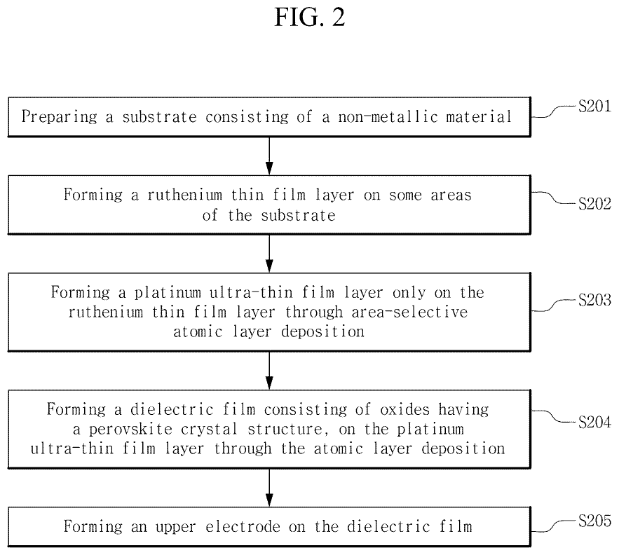

First, as shown in FIG. 2, a substrate is prepared (S201).

The substrate consists of a non-metallic material. For example, oxide-based materials such as SiO₂ and Al₂O₃ and nitride-based materials such as SiNₓ and GaNₓ may be applicable. The substrate may correspond to an interlayer insulating film of a semiconductor device.

Next, a ruthenium thin film layer is formed on some areas of the substrate (S202). The ruthenium thin film layer acts as a constitutive element of the capacitor lower electrode. The ruthenium thin film layer may be formed either through an etch patterning process after laminating the ruthenium layer on an entire surface of the substrate, or through area-selective atomic layer deposition.

With the ruthenium thin film layer being formed on some areas of the substrate, the platinum ultra-thin film layer is selectively formed on the ruthenium thin film layer through the area-selective atomic layer deposition using nucleation delay characteristic (S203).

If the substrate consists of the non-metallic material and with the ruthenium thin film layer being formed on some areas of the substrate, platinum is deposited through the atomic layer deposition, the platinum is selectively deposited only on the ruthenium thin film layer due to a difference in the surface energy between the non-metallic material and the ruthenium thin film layer. That is, since the substrate consisting of the non-metallic material has a relatively lower surface energy and the ruthenium thin film layer has a relatively higher surface energy, a platinum precursor supplied during the atomic layer deposition process is deposited only on the ruthenium thin film layer. The platinum precursor deposited on the ruthenium thin film layer reacts with a subsequently supplied oxidant to convert into platinum (Pt). By repeating the deposition cycle of such platinum precursor supply process and oxidant supply process, the platinum ultra-thin film layer can be selectively formed only on the ruthenium thin film layer.

Meanwhile, during the process of increasing a thickness of the platinum ultra-thin film layer by repeating the deposition cycle, if the deposition cycle exceeds a certain number of times, the platinum grows even on the substrate consisting of the non-metallic material. Although reaction selectivity for the platinum precursor exists between the non-metallic material and the ruthenium thin film layer, repetition of the atomic layer deposition cycle more than a certain number of times causes a decrease in the reaction selectivity, thereby showing a phenomenon that the platinum precursor is deposited even on the non-metallic material. This phenomenon is called the nucleation delay characteristic. In other words, if the deposition cycle is within a certain number of times, the platinum precursor is deposited only in the growth area (ruthenium thin film layer) of the substrate, whereas if the deposition cycle exceeds a certain number of times, the platinum precursor is deposited even in the non-growth area (non-metallic material) of the substrate to form platinum.

Repetition of the deposition cycle means that a thickness of the deposited platinum increases. If the thickness of the deposited platinum is controlled within a certain thickness, platinum can be prevented from forming in the non-growth area (non-metallic material) of the substrate. The present invention induces platinum to grow only in the ruthenium thin film layer by forming the platinum to the thickness of the ultra-thin film using this nucleation delay characteristic.

Since the thickness of the platinum ultra-thin film layer deposited through the above-described area-selective atomic layer deposition is 4 to 50 Å and the thickness of the platinum ultra-thin film layer is 5 nm or less, it is possible to selectively grow the platinum ultra-thin film layer only on the ruthenium thin film layer simultaneously with preventing the platinum from being deposited on the non-metallic material of the substrate.

In addition, the reason why the thickness of the platinum ultra-thin film layer is set to 4 to 50 Å is as follows. With Reference to Experimental Examples described later, if the thickness of the platinum ultra-thin film layer is less than 4 Å, interfacial oxides, i.e., strontium oxide (SrOₓ), are generated at the interface between the platinum ultra-thin film layer and SrTiO₃ during the subsequent SrTiO₃ deposition process, thereby deteriorating the dielectric property and the leakage current property of the capacitor. If the thickness of the platinum ultra-thin film layer exceeds 50 Å, there is a risk that the platinum ultra-thin film layer may grow on the non-metallic material during the area-selective atomic layer deposition process.

Meanwhile, when depositing the platinum ultra-thin film layer through the area-selective atomic layer deposition, the platinum precursor may include any one of (COD)Pt(CH₃)₃, (COD)Pt(CH₃)(Cp), (COD)Pt(CH₃)Cl, (Cp)Pt(CH₃)(CO), (Cp)Pt(allyl), (Cp)Pt(CH₃)₃, (MeCp)Pt(CH₃)₃, (acac)Pt(CH₃)₃, Pt(acac)₂, Pt(CH₃)₂ (CH₃) NC, Pt(HFA)₂, Pt(hfac)₂, or Pt(tmhd)₂, and the oxidant may include any one of oxygen (O₂), oxygen plasma, or ozone (O₃).

By selectively depositing the platinum ultra-thin film layer on the ruthenium thin film layer, a lower electrode having a structure in which the platinum ultra-thin film layer is laminated on the ruthenium thin film layer is completed.

Next, a dielectric film deposition process is performed using the atomic layer deposition (S204).

The dielectric film consists of oxides having a perovskite crystal structure, wherein the oxides having the perovskite crystal structure are any one of SrTiO₃, (Ba,Sr)TiO₃(BST), BaTiO₃, PZT, PLZT, (Ba, Sr)(Zr,Ti)O₃(BSZTO), Sr(Zr,Ti)O₃(SZTO), Ba(Zr,Ti)O₃(BZTO), (Ba, Sr)ZrO₃(BSZO), SrZrO₃ or BaZrO₃, or a combination thereof. Among them, SrTiO₃ will be described as an embodiment.

In order to form the dielectric film consisting of SrTiO₃ through the atomic layer deposition, a strontium oxide deposition step and a titanium oxide deposition step are repeated. A combination of the strontium oxide deposition step and the titanium oxide deposition step corresponds to one deposition cycle, and a thickness of SrTiO₃ can be increased by repeating a plurality of the deposition cycles.

The strontium oxide deposition step consists of a strontium precursor supply process and an oxidant supply process in detail. In the strontium precursor supply process, the strontium precursor is supplied for a certain period of time in a reaction chamber equipped with a substrate to adsorb the strontium precursor on the platinum ultra-thin film layer and purge the unadsorbed strontium precursor using an inert gas. Various precursors may be used as the strontium precursor, and Sr (ᵢPr₃Cp)₂ may be used as an embodiment.

The oxidant supply process is a process of supplying the oxidant into a reaction chamber while the strontium precursor is adsorbed on the platinum ultra-thin film layer, wherein a strontium oxide layer (SrO) is formed by a reaction between the strontium precursor and the oxidant. In this case, the strontium oxide layer (SrO) is formed in units of atomic layers, and H₂O may be used as the oxidant. In addition, after the strontium oxide layer (SrO) is formed, the oxidant supply process includes a process of injecting an inert gas to purge reaction by-products such as a ligand and unreacted oxidants.

The titanium oxide deposition step consists of a titanium precursor supply process and an oxidant supply process in detail. The titanium precursor supply process consists of supplying the titanium precursor to the reaction chamber to adsorb the titanium precursor on the strontium oxide layer (SrO) and purge the unadsorbed titanium precursor with an inert gas. Various precursors may be used as the titanium precursor, and C₅(CH₃)₅Ti(OMe)₃ may be used as an embodiment.

The oxidant supply process is a process of supplying the oxidant such as ozone (O₃) to the reaction chamber while the titanium precursor is adsorbed on the strontium oxide layer (SrO). As the oxidant is supplied, a titanium oxide layer (TiO₂) is formed through a reaction between the titanium precursor and the oxidant. In addition, during the oxidant supply process, solid diffusion occurs between the strontium oxide layer (SrO) and the titanium oxide layer (TiO₂) to form crystalline SrTiO₃. After the crystalline SrTiO₃ is formed, the oxidant supply process includes a process of injecting an inert gas to purge reaction by-products such as a ligand and unreacted oxidants.

Meanwhile, when performing the strontium deposition step and the titanium deposition step, it is preferable that a process temperature in the reaction chamber is set to 400° C. or lower. If the temperature exceeds 400° C., there may be a problem that the strontium precursor and titanium precursor are decomposed thermally.

Through the above process, the dielectric film consisting of SrTiO₃ is formed on the platinum ultra-thin film layer. When forming the dielectric film consisting of SrTiO₃ through the atomic layer deposition, the deposited SrTiO₃ may be amorphous or crystalline depending on a process temperature and a thickness of the dielectric film. That is, assuming that the process temperature is 400° C. or lower, the deposited SrTiO₃ forms an amorphous state at a relatively lower process temperature and a crystalline state at a relatively higher process temperature. Additionally, as a thickness of the deposited SrTiO₃ increases, it is converted from the amorphous state to the crystalline state. Referring to Experimental Examples described later, on the basis of the process temperature of 380° C., SrTiO₃ having the thickness of 7.7 nm formed the amorphous state, and SrTiO₃ having the thickness of 15.4 nm formed the crystalline state.

When the deposited dielectric film is in the amorphous state, a heat treatment process may be selectively applied to crystallize the dielectric film. The heat treatment process is carried out at 500° C. or lower, which meets the limit process temperature of 500° C. to prevent deterioration of the device in a DRAM process. By selectively performing the heat treatment process of 500° C. or lower, the amorphous dielectric film can be converted to the crystalline state.

With the crystalline dielectric film being completed through the above process, the method for manufacturing the capacitor according to an embodiment of the present invention is completed by forming an upper electrode on the dielectric film (S205). A material constituting the upper electrode may be platinum (Pt) or a known electrode material.

As mentioned above, a capacitor and a method for manufacturing the capacitor according to an embodiment of the present invention have been described. Hereinafter, the present invention will be described through Experimental Examples in more detail.

### Experimental Example 1: Area-Selective Deposition of Platinum Ultra-Thin Film Layer

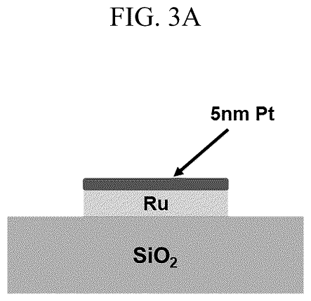

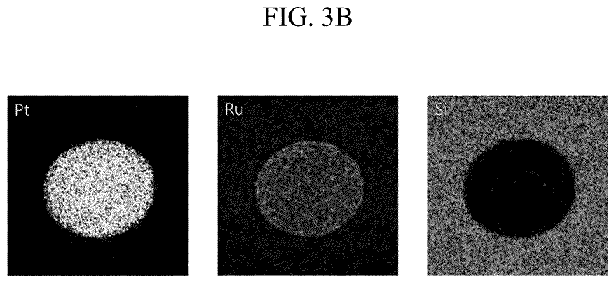

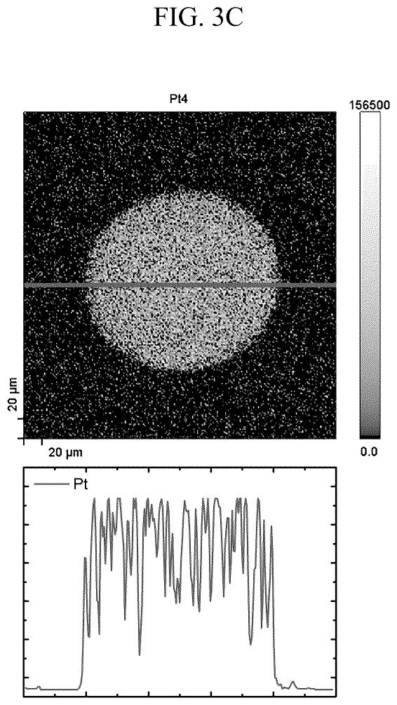

A SiO₂ substrate on which a Ru layer was formed locally was prepared, and platinum (Pt) was deposited on the substrate to a thickness of 5 Å by atomic layer deposition (see FIG. 3A). A size of the SiO₂ substrate is 2×2 cm², and the Ru layer is 200 μm in diameter and 50 nm in thickness. In the platinum deposition, the platinum precursor was (MeCp)Pt(CH₃)₃, O₂ was used as the oxidant, and the deposition cycle was repeated 10 times.

After the platinum deposition, auger electron spectroscopy (AES) analysis and line profile analysis were performed. As a result of the AES analysis (see FIG. 3B), it can be confirmed that platinum (Pt) was selectively deposited only on the Ru layer. A result of the line profile analysis conducted for more accurate analysis (see FIG. 3C) also showed that a peak intensity of platinum (Pt) increased only in an area of the Ru layer, which confirms that platinum (Pt) was area-selectively deposited.

### Experimental Example 2: Sr Areal Density and Sr Atomic Ratio According to Thickness of Platinum Ultra-Thin Film Layer

In order to confirm whether SrOₓ, which is the interfacial oxides, is generated at an interface between the platinum ultra-thin film layer and SrTiO₃ during the deposition of SrTiO₃, an experiment was conducted by varying a deposition thickness of the platinum ultra-thin film layer, and a Sr areal density and a Sr atomic ratio were analyzed to determine whether SrOₓ was generated.

For the experiment, a substrate having a lower electrode was prepared. The lower electrode had a structure in which the platinum ultra-thin film layer was laminated on the ruthenium thin film layer, and samples having the platinum ultra-thin film layers of 2, 3, 4, 5, 6, and 10 Å in thickness were prepared, respectively. In addition, a sample in which the lower electrode consisted only of ruthenium (Ru) and a sample in which the lower electrode consisted only of platinum (Pt) were also prepared for comparison, and the experiment was conducted under the same conditions.

The substrate having the platinum ultra-thin film layer of different thickness, the Ru lower electrode substrate, and the Pt lower electrode substrate were charged into an ALD reaction chamber, respectively, and Sr (ᵢPr₃Cp)₂ was supplied at 380° C. for 6 seconds, followed by a N₂ gas was supplied for 15 seconds to perform purging. Then, H₂O was supplied for 1 second and purged for 60 seconds using the N₂ gas. Next, Cs (CH₃)₅Ti(OMe)₃ was supplied for 6 seconds and the N₂ gas was supplied for 20 seconds to perform purging. Then, O₃ was supplied for 5 seconds and purged using the N₂ gas for 10 seconds. The above deposition cycle was repeated 150 times.

After the deposition of SrTiO₃ was completed, a Sr areal density and a Sr atomic ratio were measured for each of the samples.

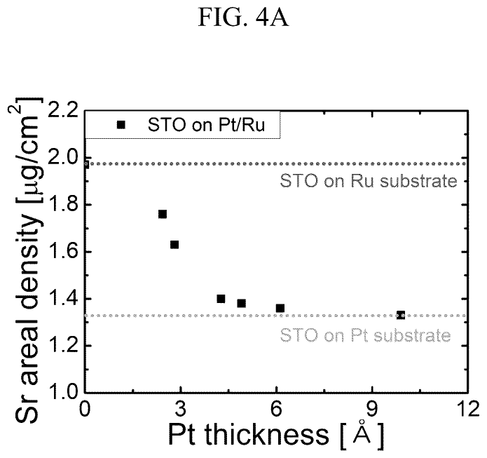

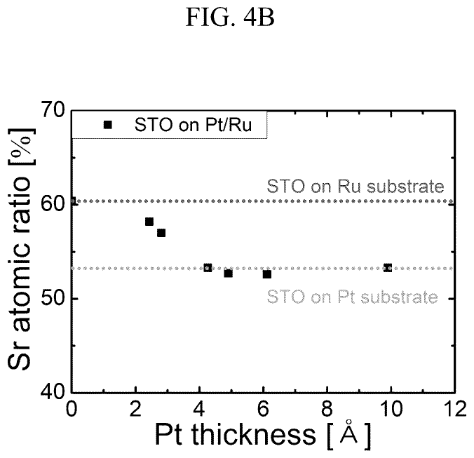

First, referring to FIG. 4A, the sample in which SrTiO₃ was deposited on the Ru lower electrode showed the Sr areal density of about 1.97 μg/cm², and the sample in which SrTiO₃ was deposited on the Pt lower electrode showed the Sr areal density of about 1.33 μg/cm².

When SrTiO₃ was deposited on the platinum ultra-thin film layer, the Sr areal density tended to decrease as a thickness of the platinum ultra-thin film layer increased. In detail, it could be confirmed that when SrTiO₃ was deposited on the platinum ultra-thin film layer of 4 Å or more, the Sr areal density was maintained constant and had a numerical value almost similar to the Sr areal density of the sample in which SrTiO₃ was deposited on the Pt lower electrode.

These results mean that in the platinum ultra-thin film layer of 3 Å or less, oxides with excess Sr, i.e., strontium oxide (SrOₓ), were generated due to the oxidation of Ru and the oxygen scavenging effect of RuO₂, and that in the platinum ultra-thin film layers of 4 Å or more, the oxidation of Ru was suppressed and strontium oxide (SrOₓ) was not generated so that the oxides that meet the stoichiometry of SrTiO₃ were formed.

The tendency of these Sr areal density results is consistent with that of the Sr atomic ratio results.

Referring to FIG. 4B, the Sr atomic ratio tended to decrease as a thickness of the platinum ultra-thin film layer increased. In addition, it could be confirmed that when SrTiO₃ was deposited on the platinum ultra-thin film layer of 4 Å or more, the Sr atomic ratio was maintained constant and had a numerical value almost similar to the Sr atomic ratio of the sample in which SrTiO₃ was deposited on the Pt lower electrode. It could be seen through these results that strontium oxide (SrOₓ) was generated on the platinum ultra-thin film layer of 3 Å or less, and that the oxidation of Ru was suppressed on the platinum ultra-thin film layer of 4 Å or more not to generate strontium oxide (SrOₓ).

### Experimental Example 3: Sr Areal Density and Sr Atomic Ratio According to the Number of Deposition Cycles

During the deposition of SrTiO₃, a Sr areal density and a Sr atomic ratio were analyzed depending on the number of deposition cycles to determine whether SrOₓ was generated.

The experimental conditions were applied in the same manner as in Experimental Example 2, except that the platinum ultra-thin film layer of the samples had a thickness of 5 Å and 10 Å and the lower electrode of the samples consisted only of ruthenium (Ru). The deposition cycle was repeated 400 times, and the Sr areal density and the Sr atomic ratio were measured for the deposited oxides at each period of a certain deposition cycle.

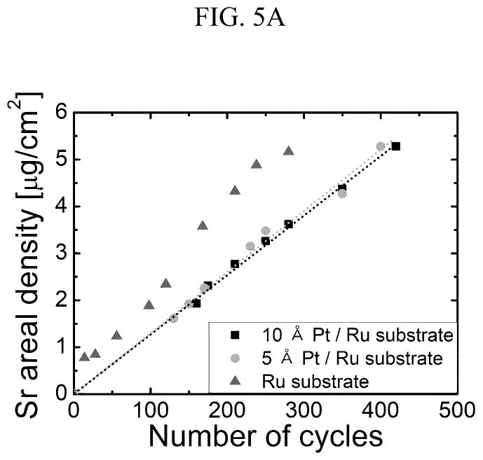

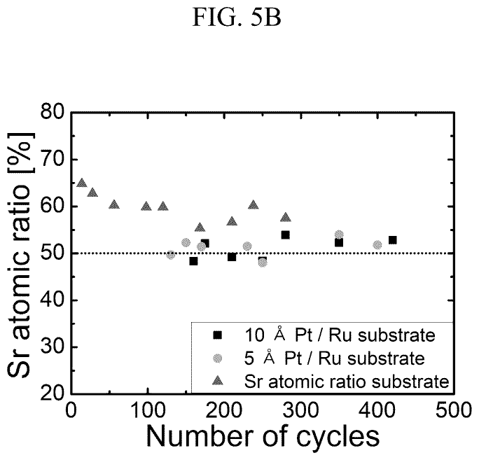

In the case of the Sr areal density (see FIG. 5A), it was confirmed that the oxides deposited on the platinum ultra-thin film layer showed a tendency for the Sr areal density to increase linearly regardless of a thickness of the platinum ultra-thin film layer, whereas the oxides deposited on the ruthenium (Ru) lower electrode showed a tendency for the Sr areal density to increase rapidly during the initial deposition cycles of 10 or less and increase linearly after that.

These results mean that the oxides formed on the ruthenium (Ru) lower electrode in the initial deposition cycles of 10 or less are oxides with an excess of strontium (Sr), and can be construed that as the deposition cycle is repeated 10 times or more, an excess of strontium (Sr) is gradually eliminated to form the oxides that conform to the stoichiometry of SrTiO₃.

On the other hand, it can be seen that the Sr areal density of the oxides formed on the platinum ultra-thin film layer (5 Å, 10 Å) increases steadily (linearly) with the increase of the deposition cycle regardless of the number of deposition cycles, and therefore the oxides with excess strontium (Sr) are not formed in the initial deposition cycles.

The Sr atomic ratio results are consistent with the Sr areal density results.

Referring to FIG. 5B, the oxides formed on the platinum ultra-thin film layer showed the Sr atomic ratio of a constant numerical value (about 50 to 54 at %) regardless of increase in the deposition cycle, whereas the oxides formed on the ruthenium (Ru) lower electrode showed the highest Sr atomic ratio of about 65 at % during the initial deposition cycles of 10 or less, and the Sr atomic ratio showed a tendency to gradually decrease as the deposition cycle increased. Even through these Sr atomic ratio measurement results, it can be seen that the oxides formed on the ruthenium (Ru) lower electrode during the initial deposition cycles of 10 or less are oxides with an excess of strontium (Sr).

Further, it can be seen from the results of FIG. 5B that the oxides formed on the ruthenium (Ru) lower electrode showed a tendency for the Sr atomic ratio to gradually decrease as the deposition cycle increase, but showed irregular numerical values of the Sr atomic ratio without indicating uniform numerical values as in the oxides formed on the platinum ultra-thin film layer. From these results, it can be inferred that the oxides formed on the platinum ultra-thin film layer conforms to the stoichiometry of SrTiO₃ during the initial deposition cycles, whereas it can be determined that the oxides formed on the ruthenium (Ru) lower electrode do not conform well to the stoichiometry of SrTiO₃ even though the initial deposition cycles as well as the deposition cycles are increased.

### Experimental Example 4: Analysis of Crystallinity of SrTiO₃ Depending on Lower Electrode Material

SrTiO₃ was deposited by applying the experimental conditions of Experimental Example 2 to a lower electrode in which the platinum ultra-thin film layer having a thickness of 4 Å was laminated on the ruthenium thin film layer, a lower electrode consisting only of platinum (Pt), and a lower electrode consisting only of ruthenium (Ru), respectively, and GIXRD analysis was performed for the deposited SrTiO₃.

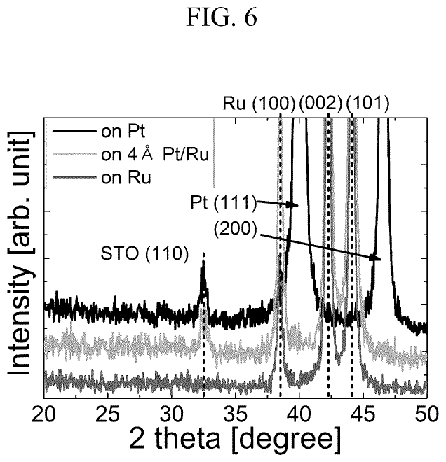

As a result of the GIXRD analysis (see FIG. 6), SrTiO₃ deposited on the Pt lower electrode and the platinum ultra-thin film layer of 4 Å thickness showed a characteristic peak corresponding to a crystal surface (110) of the crystalline SrTiO₃, whereas SrTiO₃ deposited on the Ru lower electrode did not show the characteristic peak corresponding to the crystal surface (110). It can be seen from these results that when SrTiO₃ was deposited on the platinum ultra-thin film layer of 4 Å thickness, SrOₓ, the interfacial oxides, was not generated so that the crystalline SrTiO₃ conforming to the stoichiometry was produced without a heat treatment, whereas SrTiO₃ deposited on the Ru lower electrode was in an amorphous state.

### Experimental Example 5: Dielectric Constant, Equivalent Oxide Film Thickness (EOT), and Leakage Current Property

SrTiO₃ was laminated to a thickness of 7.7 to 15.4 nm on the platinum ultra-thin film layer by applying the experimental conditions of Experimental Example 2 to the platinum ultra-thin film layer having a thickness of 10 Å, and then an upper electrode was formed on the SrTiO₃ to manufacture a capacitor. A dielectric constant and an equivalent oxide film thickness (EOT) characteristic were analyzed for the manufactured capacitor.

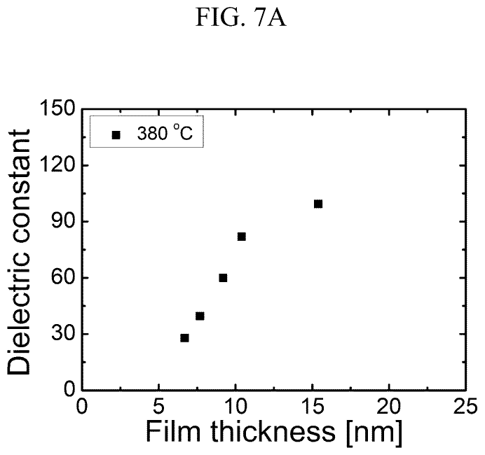

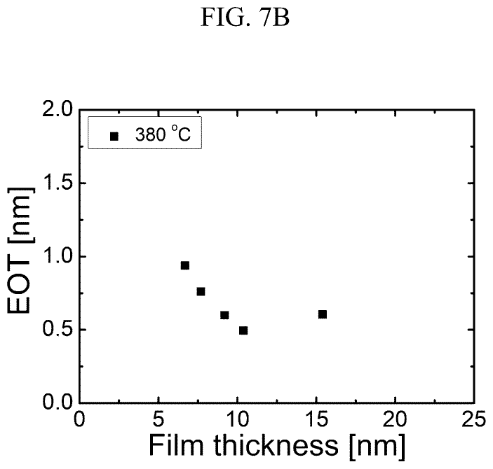

In the case of the dielectric constant (see FIG. 7A), it can be confirmed that when a thickness of SrTiO₃ was 7.7 nm, the dielectric constant (k) showed approximately 30, and that the dielectric constant increased with a higher slope as the thickness of SrTiO₃ increased up to 15.4 nm. This result indicates that the crystallinity of SrTiO₃ is improved as the deposition thickness of SrTiO₃ becomes thicker.

In the case of the equivalent oxide film thickness (EOT) (see FIG. 7B), it can be confirmed that as the deposition thickness of SrTiO₃ increases, the equivalent oxide film thickness (EOT) tends to decrease, thereby enhancing the crystallinity to improve capacitance characteristic.

In order to examine the dielectric constant and the equivalent oxide film thickness (EOT) characteristic by applying the subsequent heat treatment process, the deposited SrTiO₃ was heat treated under an oxygen atmosphere at 500° C. for 30 minutes, followed by being applied to the capacitor, and the dielectric constant and the equivalent oxide film thickness (EOT) characteristic for each capacitor were analyzed.

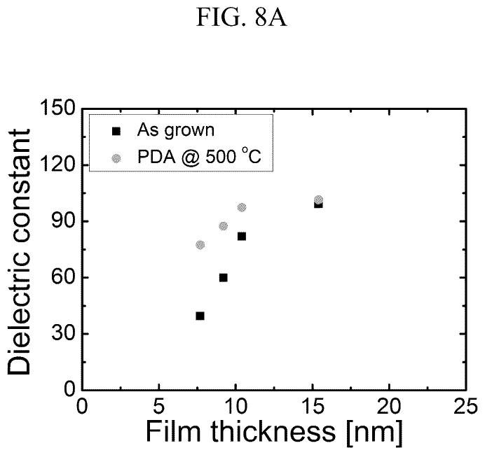

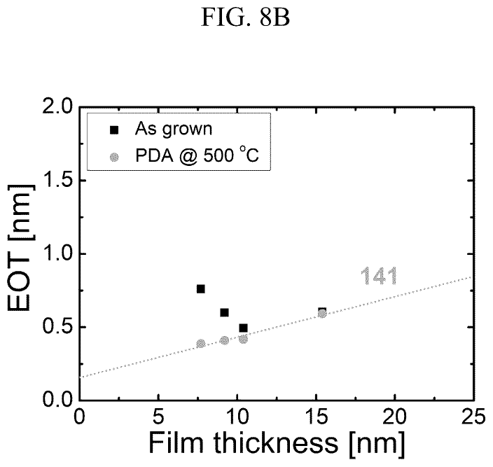

Looking at the dielectric constant and the equivalent oxide film thickness (EOT) characteristic after the heat treatment, it can be confirmed that both the dielectric constant and the equivalent oxide film thickness (EOT) characteristic are enhanced, as shown in FIGS. 8A and 8B.

Furthermore, leakage current property was analyzed depending on the equivalent oxide film thickness (EOT) before and after applying the subsequent heat treatment process.

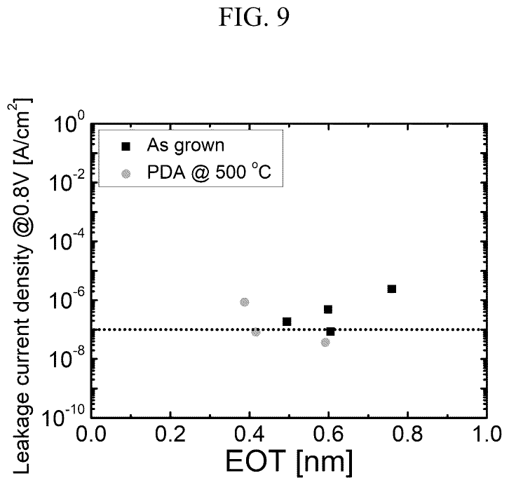

Referring to FIG. 9, it can be seen that the leakage current property are further improved when the heat treatment is applied. The heat-treated capacitor secured the equivalent oxide film thickness (EOT) of 4.0 Å, and the leakage current property showed a very low result value of 8.4×10-8 A/cm² at a DRAM operating voltage of 0.8V. This leakage current property satisfies the value of 10-7 A/cm² or less which is required for the DRAM operating voltage (0.8V).

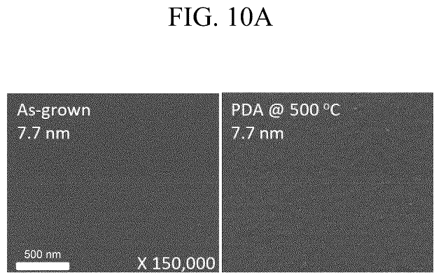

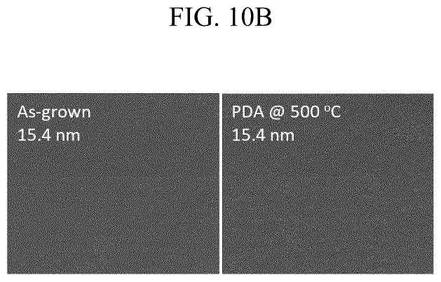

Meanwhile, as a result of SEM analysis on the SrTiO₃ surface before and after applying the subsequent heat treatment process (see FIGS. 10A and 10B), no defects or microcracks were observed regardless of the deposition thickness of SrTiO₃ and whether or not the heat treatment process was applied, which means that the thin film of a high density and high quality was deposited well from the beginning of growth of SrTiO₃, and the no device deterioration occurred even after the heat treatment.

### DESCRIPTION OF DRAWING SYMBOLS

110: Lower electrode 111: Ruthenium thin film layer
112: Platinum ultra-thin film layer 120: Dielectric film
130: Upper electrode

What is claimed is:

1. A capacitor characterized by comprising a lower electrode having a structure in which a platinum ultra-thin film layer is laminated on a ruthenium thin film layer;
a dielectric film laminated on the platinum ultra-thin film layer; and
an upper electrode laminated on the dielectric film.

2. The capacitor according to claim 1, characterized in that the platinum ultra-thin film layer has a thickness of 50 Å or less.

3. The capacitor according to claim 1, characterized in that the platinum ultra-thin film layer has a thickness of 10 Å or less.

4. The capacitor according to claim 1, characterized in that the platinum ultra-thin film layer has a thickness of 4 to 10 Å.

5. The capacitor according to claim 1, characterized in that the dielectric film consists of oxides having a perovskite crystal structure,
wherein the oxides having the perovskite crystal structure are any one of SrTiO₃, (Ba,Sr)TiO₃(BST), BaTiO₃, PZT, PLZT, (Ba,Sr)(Zr,Ti)O₃(BSZTO), Sr(Zr,Ti)O₃(SZTO), Ba(Zr,Ti)O₃(BZTO), (Ba,Sr)ZrO₃(BSZO), SrZrO₃ or BaZrO₃, or a combination thereof.

6. The capacitor according to claim 1, characterized by having an equivalent oxide film thickness (EOT) of 4.0 Å or less and a leakage current value of 8.4×10-8 A/cm² at an operating voltage of 0.8 V.

7. A method for manufacturing a capacitor, characterized by comprising the steps of:
preparing a substrate consisting of a non-metallic material;
forming a ruthenium thin film layer on some areas of the substrate;
forming a platinum ultra-thin film layer on the ruthenium thin film layer through area-selective atomic layer deposition;
forming a dielectric film on the platinum ultra-thin film layer through the atomic layer deposition; and
forming an upper electrode on the dielectric film.

8. The method for manufacturing the capacitor according to claim 7, characterized in that in the step of forming the platinum ultra-thin film layer on the ruthenium thin film layer through the area-selective atomic layer deposition,
the platinum ultra-thin film layer is formed only on the ruthenium thin film layer having relatively higher surface energy due to a difference in the surface energy between the non-metallic material and the ruthenium thin film layer.

9. The method for manufacturing the capacitor according to claim 7, characterized in that the platinum ultra-thin film layer is laminated to a thickness of 50 Å or less.

10. The method for manufacturing the capacitor according to claim 7, characterized in that the platinum ultra-thin film layer is laminated to a thickness of 10 Å or less.

11. The method for manufacturing the capacitor according to claim 7, characterized in that the platinum ultra-thin film layer is laminated to a thickness of 4 to 10 Å.

12. The method for manufacturing the capacitor according to claim 7, characterized in that the dielectric film consists of oxides having a perovskite crystal structure,
wherein the oxides having the perovskite crystal structure are any one of SrTiO₃, (Ba,Sr)TiO₃(BST), BaTiO₃, PZT, PLZT, (Ba,Sr)(Zr,Ti)O₃(BSZTO), Sr(Zr,Ti)O₃(SZTO), Ba(Zr,Ti)O₃(BZTO), (Ba,Sr)ZrO₃(BSZO), SrZrO₃ or BaZrO₃, or a combination thereof.

13. The method for manufacturing the capacitor according to claim 7, characterized in that in the step of forming the dielectric film on the platinum ultra-thin film layer through the atomic layer deposition, a process temperature of the atomic layer deposition is 400° C. or less.

14. The method for manufacturing the capacitor according to claim 7, characterized by further comprising the step of heat treating the dielectric film at a temperature of 500° C. or lower after the step of forming the dielectric film on the platinum ultra-thin film layer through the atomic layer deposition.

15. The method for manufacturing the capacitor according to claim 7, characterized in that the manufactured capacitor has an equivalent oxide film thickness (EOT) of 4.0 Å or less and a leakage current value of 8.4×10-8 A/cm² at an operating voltage of 0.8 V.
